(19) United States
(12) Patent Application Publication
(10) Pub. No.: US 2014/0034955 A1
(43) Pub. Date: Feb. 6, 2014

(54) Nano-MOS Devices and Method of Making

(71) Applicants: Dongping Wu, Shanghai (CN); Cheng Hu, Shanghai (CN); Luo Zhu, Shanghai (CN); Zhiwei Zhu, Shanghai (CN); Shili Zhang, Uppsala (SE); Wei Zhang, Shanghai (CN)

(72) Inventors: Dongping Wu, Shanghai (CN); Cheng Hu, Shanghai (CN); Luo Zhu, Shanghai (CN); Zhiwei Zhu, Shanghai (CN); Shili Zhang, Uppsala (SE); Wei Zhang, Shanghai (CN)

(73) Assignee: FUDAN UNIVERSITY, Shanghai (CN)

(21) Appl. No.: 13/519,315

(22) PCT Filed: Oct. 31, 2011
(86) PCT No.: PCT/CN11/81565

§ 371 Date: Jun. 26, 2012

(30) Foreign Application Priority Data
Apr. 26, 2011 (CN) 201110106317.X

(51) Int. Cl. H01L 21/285; H01L 29/04; H01L 29/423; H01L 29/66; H01L 29/78; H01L 29/41

(52) U.S. Cl. CPC H01L 21/28518; H01L 29/78; H01L 29/413; H01L 29/42376; H01L 29/66477; H01L 29/04
USPC 257/66; 438/285

(57) ABSTRACT

The present invention discloses a method of making nano-MOS devices having a metal gate, thereby avoiding the poly depletion effect, and enhancing the MOS device's performance. The method forms metal gates by depositing a metal film over sidewall surfaces on two sides of a polycrystalline semiconductor layer. The metal in the metal film diffuses toward the sidewall surfaces of the polycrystalline semiconductor layer and forms, after annealing, metal-semiconductor compound nanowires (i.e., metal gates) on the sidewall surfaces of the polycrystalline semiconductor layer. Thus, high-resolution lithography is not required to form metal compound semiconductor nanowires, resulting in significant cost saving. At the same time, a nano-MOS device is also disclosed, which includes a metal gate, thereby avoiding the poly depletion effect, and resulting in enhanced MOS device performance.

### FIELD

The present invention is related to semiconductor processing technologies, and more particularly to nano-scale MOS devices (Nano-MOS Devices) and method of making

### BACKGROUND

Since the invention of the first transistor and after decades of rapid development, lateral and longitudinal dimensions of transistors have shrunk drastically. According to the forecast of International Technology Roadmap for Semiconductors (ITRS), the feature sizes of transistors may reach 7 nm by 2018. The continual reduction in the feature sizes results in continual enhancement of the performance (speed) of transistors. It also enables us to integrate more devices on a chip of the same area, making integrated circuit with better and better performance while at the same time reducing unit function costs.

The continued shrinking in device feature sizes, however, also brings a series of challenges. Because the gate electrodes of conventional MOS devices typically use polysilicon, poly depletion effect (PDE) occurs when the feature sizes of conventional transistors with polysilicon gates have shrunk to a certain degree, preventing further enhancement in the performance of the transistors. The so-called poly depletion effect refers to a depletion layer being formed in the polysilicon gate when the transistor is in the on-state. Because the depletion layer superimposes on the gate oxide layer, an effective gate oxide thickness observed from an electrical perspective is the sum of the actual thickness of the gate oxide and the thickness of the poly depletion layer, resulting in increased effective gate oxide thickness and reduced transistor turn-on current.

Metal gates emerged in the efforts to solve the above-mentioned poly depletion effect problem. The so-called metal gate refers to metal being used as the gate of a MOS transistor. Because metal has relatively high conductivity, the metal gate can avoid gate depletion effect, making the MOS devices to have better performance.

However, the fabrication of nano-scale metal gates still has some technical difficulties. This is because the currently attainable minimum size for the metal gate depends mainly on lithography, and the resolution of current lithography system has not yet reached the range of a few nanometers. Moreover, lithography systems are expensive, and the associated processes are too costly.

Therefore, how to fabricate nano-scale metal gate and MOS devices has become the technological problems much needed to be solved by the industry.

### SUMMARY

The present invention purports to provide a nano-MOS device and a method for making the nano-MOS device, in order to reduce the feature sizes of MOS devices, and to improve the performance of MOS devices.

To solve the above problems, the present invention provides a method of making a nano-MOS devices, the method comprising:

(1) providing a semiconductor substrate;

(2) fabricating a gate oxide layer on the semiconductor substrate;

(3) fabricating a gate over the gate oxide layer, and forming side walls on both sides of the gate, wherein, the gate includes one or more metal-semiconductor compound nanowires; and

(4) performing source/drain implants to form source/drain regions in the semiconductor substrate;

wherein, Step (3) more specifically includes the following substeps:
forming consecutively a polycrystalline semiconductor layer and an insulating layer on the gate oxide layer;
etching consecutively the insulating layer and the polycrystalline semiconductor layer to remove the insulating layer and polycrystalline semiconductor layer on two sides;
depositing a metal film on sidewalls of the polycrystalline semiconductor layer, the metal in the metal film diffusing toward the polycrystalline semiconductor layer;
removing the metal film remaining on the sidewalls of the polycrystalline semiconductor layer;
annealing the polycrystalline semiconductor layer, to form metal/semiconductor compound nanowires on sidewall surfaces of the polycrystalline semiconductor layer;
removing the insulating layer and the polycrystalline semiconductor layer;
etching the gate oxide layer using the metal/semiconductor compound nanowires as mask; and
forming sidewalls on two sides of respective metal/semiconductor compound nanowires.

In some embodiments, the gate is about 2˜11 nm long.

In some embodiments, the metal film is deposited onto the sidewalls on two sides of the polycrystalline semiconductor layer using a PVD process.

In some embodiments, a target material is partially ionized into an ionic state so as to produce metal ions, and a first bias voltage is applied to the polycrystalline semiconductor layer during the deposition of the metal film using the PVD method.

In some embodiments, a second bias voltage is applied on the target material to partially ionize the target material into the ionic state.

In some embodiments, the first bias voltage is any of a direct current bias voltage, an alternating current bias voltage or a pulsed biase voltage.

In some embodiments, the second bias voltage is any of a direct current bias voltage, an alternating current bias voltage or a pulsed biase voltage.

In some embodiments, the gate oxide layer is a high-K dielectric layer.

In some embodiments, the semiconductor substrate is silicon or silicon-on-insulator, the polycrystalline semiconductor layer is a polysilicon layer, and the metal-semiconductor-compound nanowires are metal silicide nanowires.

In some embodiments, the semiconductor substrate is germanium or germanium-on-insulator, the polycrystalline semiconductor layer is a polycrystalline germanium layer, and the metal-semiconductor-compound nanowires are metal germanide nanowires.

In some embodiments, the metal-semiconductor-compound nanowires are formed from chemical reaction between metal and the polycrystalline semiconductor layer, wherein, the metal can be any of nickel, cobalt, titanium, and ytterbium, or any of nickel, cobalt, titanium, and ytterbium incorporated with platinum.

In some embodiments, the metal is further incorporated with tungsten and/or molleybdem.

In some embodiments, the substrate is at a temperature of 0˜300° C. during the deposition of the metal film on the sidewalls on two sides of the polycrystalline semiconductor layer.

In some embodiments, the annealing temperature is about 200˜900° C.

At the same time, in order to solve the above problems, the present invention further provides a nano-MOS device fabricated using the above method for making nano-MOS devices. The nano-MOS device comprises:

a semiconductor substrate;

a gate oxide layer formed over the semiconductor substrate;

a gate formed over the gate oxide layer and having sidewalls on two sides thereof; and

source/drain regions formed in the semiconductor substrate on two sides of the gate.

In some embodiments, the gate is about 2˜11 nm long.

In some embodiments, the gate oxide layer is a high-K dielectric layer.

In some embodiments, the semiconductor substrate is silicon or silicon-on-insulator, and the metal-semiconductor-compound nanowire is a metal silicide nanowire.

In some embodiments, the semiconductor substrate is germanium or germanium-on-insulator, and the metal-semiconductor-compound nanowire is a metal germanide nanowire.

Compared to conventional technologies, the gate fabricated using the method for making a nano-MOS device according to embodiments of the present invention is a metal gate, thereby avoiding the poly depletion effect and enhancing the MOS device performance. The method forms metal gates by depositing a thin metal film on sidewall surfaces on two sides of a polycrystalline semiconductor layer. The metal in the metal film diffuses toward the sidewall surfaces of the polycrystalline semiconductor layer and forms, after annealing, metal-semiconductor-compound nanowires (i.e., metal gates) at the sidewall surfaces of the polycrystalline semiconductor layer. Thus, no high-resolution photolithography technology is required to form the metal-semiconductor-compound nanowires, resulting in significant cost saving.

Compared to conventional technologies, the gate of the nano-MOS device provided by the present invention includes a metal gate, thereby avoiding the poly depletion effect, resulting in enhanced MOS device performance.

### BRIEF DESCRIPTION OF THE DRAWINGS

FIG. 1 is a flowchart illustrating a method for making a nano-MOS device, as provided by embodiments of the present invention;

FIGS. 2A to 2J are device cross-sectional diagrams corresponding to respective steps in the method for making the nano-MOS device, as provided by embodiments of the present invention.

FIG. 3 is a cross-sectional diagram of a nano-MOS device, as provided by embodiments of the present invention.

### DESCRIPTION OF EMBODIMENTS

A nano-MOS device and a method of making the nano-MOS device, as provided by embodiments of the present invention, are described in more detail below with respect to the drawings. The advantages and characteristics of the present invention will become clearer according to the description below and the claims. It should be noted that the drawings use simplified form and inaccurate proportions, and should only be used to aid in easily and clearly describing the embodiments

As a key idea of the present invention, a method for making a nano-MOS device is provided. The nano-MOS device has a metal gate, so as to avoid the poly depletion effect and achieve enhanced MOS device performance. The method forms the metal gate by depositing a thin metal film on sidewall surfaces on two sides of a polycrystalline semiconductor layer. The metal in the metal film diffuses toward the sidewall surfaces of the polycrystalline semiconductor layer and, after annealing, forms metal-semiconductor-compound nanowires (i.e., metal gates) at the sidewall surfaces of the polycrystalline semiconductor layer. Thus, no high-resolution photolithography technology is required to form the metal-semiconductor-compound nanowires, resulting in significant cost saving. Also, a nano-MOS device is provided. The gate of the nano-MOS device includes a metal gate, thereby avoiding the poly depletion effect, resulting in enhanced MOS device performance.

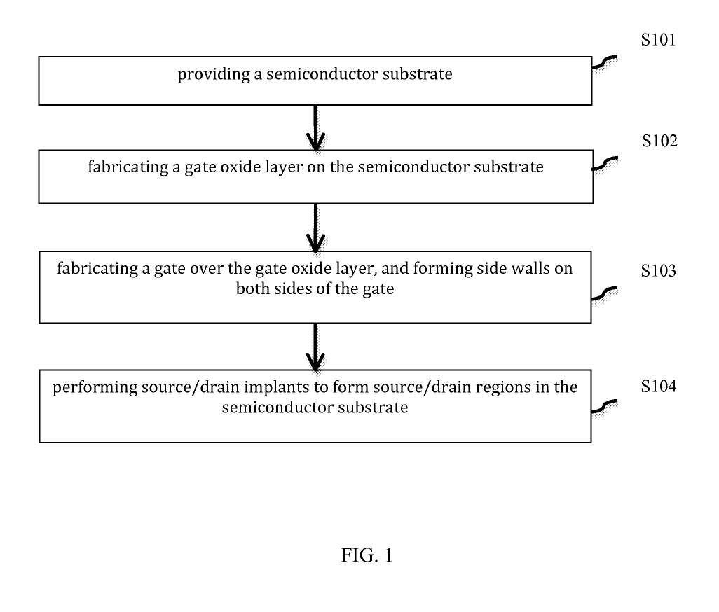

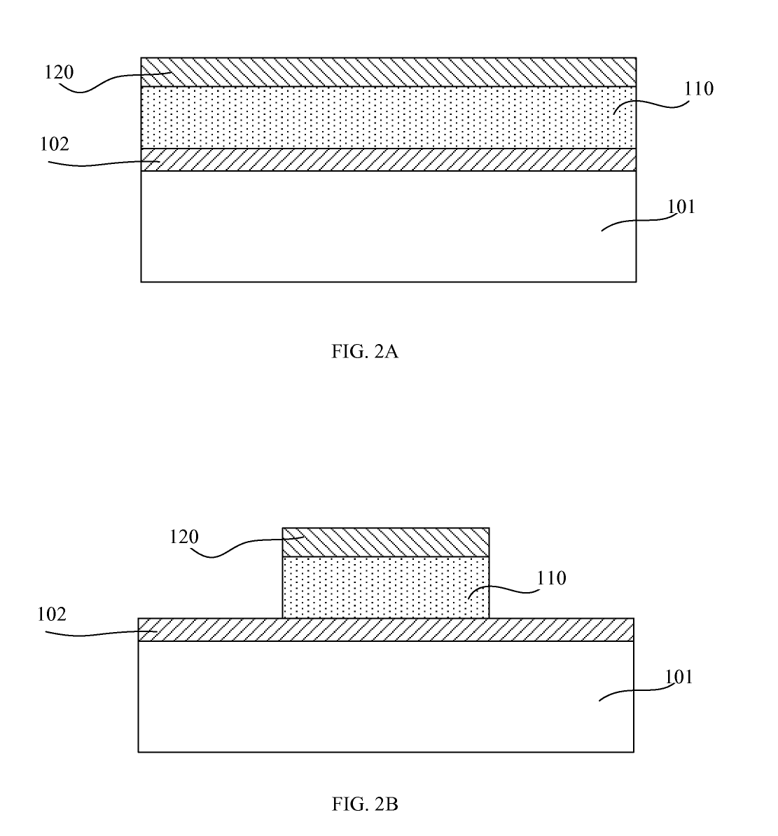

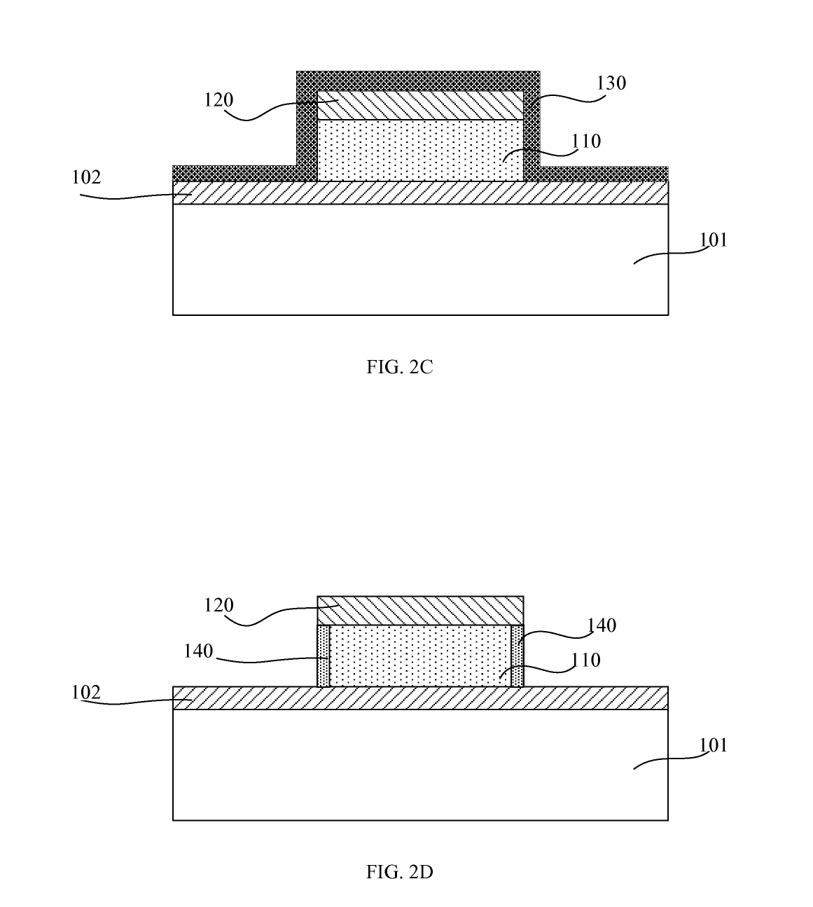

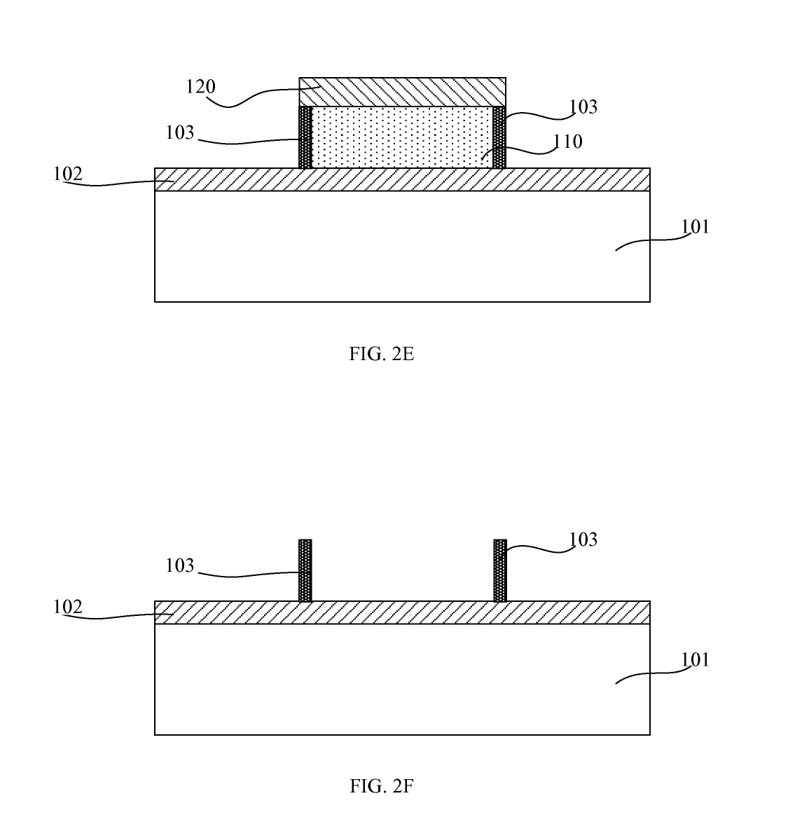

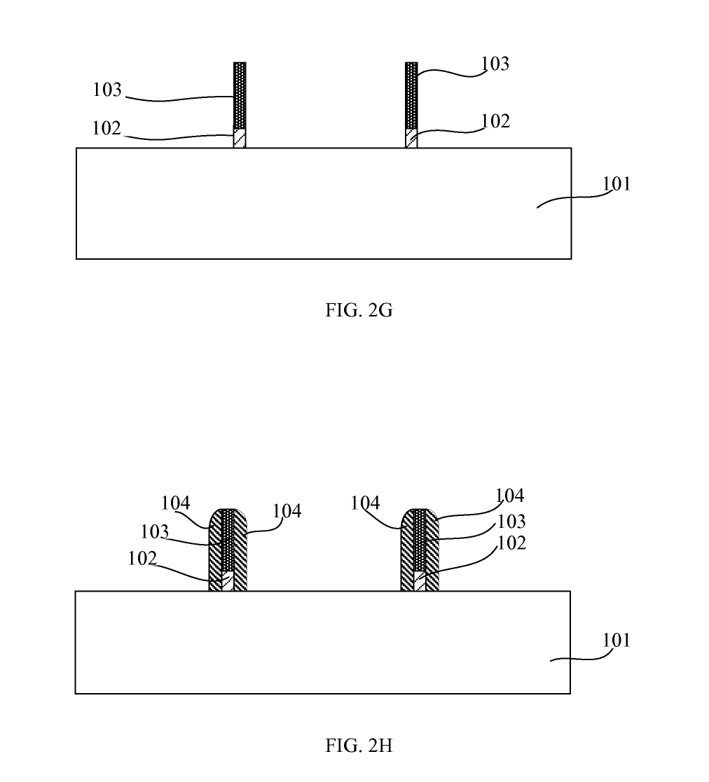

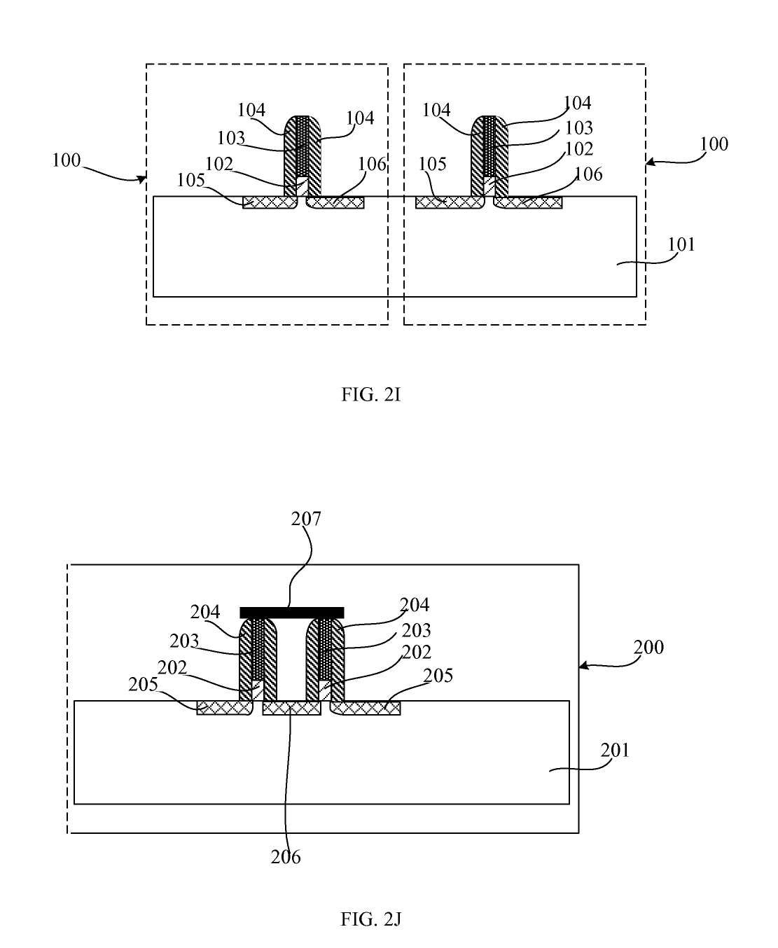

Reference is now made to FIG. 1 and FIGS. 2A to 2J, where FIG. 1 is a flowchart illustrating a method for making a nano-MOS device, as provided by embodiments of the present invention, and FIGS. 2A to 2J are device cross-sectional diagrams corresponding to respective steps in the method for making the nano-MOS device, as provided by embodiments of the present invention. As shown in FIG. 1, and FIGS. 2A to 2J, a method of making a nano-MOS device 100 comprises:

S101—providing a semiconductor substrate;

S102—fabricating a gate oxide layer 102 on the semiconductor substrate 101, wherein the gate oxide layer 102 is a high-K dielectric layer;

S103—fabricating a gate over the gate oxide layer 102, and forming side walls 104 on two sides of the gate, wherein, the gate includes one or more metal-semiconductor compound nanowires 103; wherein fabricating the gate over the gate oxide layer 102 further comprises:
forming consecutively a polycrystalline semiconductor layer 110 and an insulating layer 120 on the gate oxide layer 102, as shown in FIG. 2A;
etching consecutively the insulating layer 120 and the polycrystalline semiconductor layer 110 to remove the insulating layer 120 and polycrystalline semiconductor layer 110 on two sides, as shown in FIG. 2B;
depositing a metal film 130 on sidewalls on the two sides of the polycrystalline semiconductor layer 110, as shown in FIG. 2C, the metal in the metal film 130 diffusing toward the polycrystalline semiconductor layer 110;
removing remaining metal film 130 from sidewalls of the polycrystalline semiconductor layer 110, as shown in FIG. 2D, a metal-containing thin semiconductor layer 140 being formed at surfaces of the polycrystalline semiconductor layer 110 after the metal diffuses to the surfaces of the polycrystalline semiconductor layer 110;
annealing the polycrystalline semiconductor layer 110 to form metal/semiconductor compound nanowires 103 on sidewall surfaces of the polycrystalline semiconductor layer 110, as shown in FIG. 2E;
removing the insulating layer 120 and the polycrystalline semiconductor layer 110, as shown in FIG. 2F;
etching the gate oxide layer 102 using the metal/semiconductor compound nanowires 103 as mask, a cross-sectional diagram of device after the etching being shown in FIG. 2G; and
forming sidewalls 104 on two sides of each metal/semiconductor compound nanowire 103, as shown in FIG. 2H; and

S104—performing source/drain implants to form source/drain regions in the semiconductor substrate 101, wherein a source region 106 and a drain region 107 are formed in the semiconductor substrate 101 on two sides of each gate, completing the making of the nano-MOS device 100, as shown in FIG. 2I.

In further embodiments, the gate is about 2˜11 nm long.

In further embodiments, the metal film 130 is deposited onto the sidewalls on two sides of the polycrystalline semiconductor layer 110 using a PVD method. Further, a target material is partially ionized into an ionic state so as to produce metal ions and a first bias voltage is applied to the polycrystalline semiconductor layer 110 during the deposition of the metal film 130 using the PVD method, wherein partially ionizing the target material into an ionic state is done by applying a second bias voltage on the target material, and wherein, the first bias voltage is any of a direct current bias voltage, an alternating current bias voltage or a pulsed biase voltage, and the second bias voltage is any of a direct current bias voltage, an alternating current bias voltage or a pulsed biase voltage.

By partially ionizing the target material into an ionic state, causing it to produce metal ions, and by applying the first bias voltage to the polycrystalline semiconductor layer 110, causing the metal ions to accelerate toward the sidewalls of the polycrystalline semiconductor layer 110 and to enter the polycrystalline semiconductor layer 110, more metal ions can diffuse to the sidewalls of the polycrystalline semiconductor layer 110, and greater diffusion depth can be obtained. Thus, the eventually formed metal-semiconductor-compound nanowires 103 can have increased width, and the nano-MOS device 100 provided by embodiments of the present invention can have longer gate and larger feature sizes. Therefore, the nano-MOS device 100 provided by embodiments of the present invention can have adjustable gate length. In some embodiments, the gate length of the nano-MOS device 100 can be 2˜11 nm.

Note that in one embodiment of the present invention, a second bias voltage is applied on the target material to partially ionize the target material into the ionic state. The present invention is not thus limited, however, and any means of partially ionizing the target material into an ionic state would be included in the scope of protection of the present invention.

In further embodiments, the semiconductor substrate 101 is silicon or silicon-on-insulator, the polycrystalline semiconductor layer 110 is a polysilicon layer, and the metal-semiconductor-compound nanowires 103 are metal silicide nanowires

In further embodiments, the semiconductor substrate 101 is germanium or germanium-on-insulator, the polycrystalline semiconductor layer 110 is a polycrystalline germanium layer, and the metal-semiconductor-compound nanowires 103 are metal germanide nanowires

In one embodiment of the present invention, the semiconductor substrate 101 can be silicon or silicon-on-insulator, or germanium or germanium-on-insulator. It should be noted that the present invention is not thus limited—the semiconductor substrate 101 can be a semiconductor substrate of another type, such as gallium arsenide or any other III-V semiconductor substrate.

In a further embodiment, the metal/semiconductor compound nanowire 103 is formed from metal reacting with the polycrystalline semiconductor layer 110. The metal can be any of nickel, cobalt, titanium, and ytterbium, or any of nickel, cobalt, titanium, and ytterbium with platinum incorporation. The reason for the platinum incorporation is that pure nickel silicide has poor stability under high temperature, or tends to show non-uniformity in thickness and agglomeration, or forms nickel di-silicide (NiSi₂), which has high resistivity, seriously affecting the device properties. Thus, in order to slow the growth of nickel silicide so as to prevent the nickel silicide film from agglomeration or forming nickel di-silicide, platinum can be incorporated into nickel with an appropriate ratio. The incorporation of platinum into other metals is similarly explained.

In a further embodiment, the metal is further incorporated with tungsten and/or molybdenum, in order to further control the growth of nickel silicide or platinum incorporated nickel silicide and the diffusion of nickel/platinum, and to increase the stability of the nickel silicide or platinum incorporated nickel silicide. The incorporation of tungsten and/or molybdenum into other metals is similarly explained.

Further, the substrate temperature is at 0˜300° C. when the metal film 130 is deposited on the sidewalls on two sides of the polycrystalline semiconductor layer 110. The reason for controlling the substrate temperature in this range is that nickel may react with the polycrystalline semiconductor layer 110 (e.g., polysilicon) directly to form nickel silicide when the deposition temperature exceeds 300° C., and excessive amount of nickel diffusion may happen at the same time, resulting in the loss of thickness control. Under the particular temperature, nickel would diffuse toward the polysilicon sidewalls via the surfaces but this diffusion has a saturation characteristic, i.e., the diffusion of nickel toward the polysilicon sidewalls mainly occurs in a thin layer at the silicon surfaces, forming a thin nickel layer having a certain silicon/nickel atomic ratio. The thickness of the thin nickel layer is related to the deposition temperature—the higher the temperature, the thicker the thin nickel layer. Under room temperature, an equivalent nickel thickness of the thin nickel layer is about 2 nm.

In further embodiments, the annealing temperature is about 200˜900° C.

The metal-semiconductor-compound nanowires 103 provided by embodiments of the present invention are formed on sidewall surfaces of the polycrystalline semiconductor layer 110 by first depositing a thin metal film 130 on the sidewall surfaces on two sides of the polycrystalline semiconductor layer 110. The metal in the metal film 130 diffuses toward the sidewall surfaces of the polycrystalline semiconductor layer 110 and forms, after annealing, metal-semiconductor-compound nanowires (i.e., metal gates) 103 at the sidewall surfaces of the polycrystalline semiconductor layer 110. Thus, no high-resolution photolithography technology is required to form the metal-semiconductor-compound nanowires 103, resulting in significant cost savings.

Note that in one embodiment of the present invention, two MOS devices 100 are formed using the above method. It should be recognized that the method provided by the present invention can also be used to form one transistor 200. Since transistors generally used in practice can have multi-finger gate structures, as shown in FIG. 2J, the two metal-semiconductor compound nanowires 203 formed using the method provided by the present invention together constitute the gate of the MOS transistor 200, which is disposed over the gate oxide layer 202. Sidewalls 204 are formed on two sides of the gate, and source region 205 and drain region 206 are formed in the semiconductor substrate 201 on two sides of the gate. The two metal-semiconductor nanowires 203 are connected via an electrode 207.

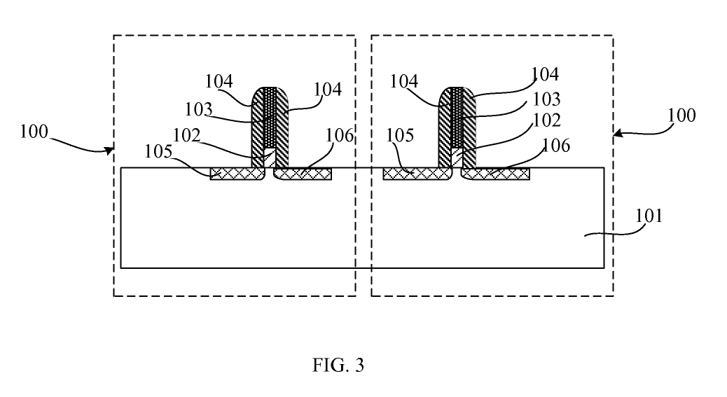

As shown in FIG. 3, which is a cross-sectional diagram of a nano-MOS device, as provided by embodiments of the present invention, the gate of the nano-MOS device 100 is a metal gate, which is about 2˜11 nm in length. The metal gate includes a metal-semiconductor compound nanowire 103. Specifically, the MOS device 100 provided by embodiments of the present invention comprises:

a semiconductor substrate 101;

a gate oxide layer 102 formed over the semiconductor substrate 101, wherein the gate oxide layer 102 is a high-k dielectric layer;

a gate formed over the gate oxide layer 102 and having sidewalls 104 formed on two sides thereof; and

source/drain regions formed in the semiconductor substrate 101 on two sides of the gate, wherein the source/drain regions include a source region 105 and a drain region 106 formed in the semiconductor substrate 101 on respective sides of the gate.

In the MOS device provided by embodiments of the present invention, the gate length is only 2˜11 nm. According to integrated circuit scaling rules, the other geometrical parameters associated with the nano-MOS device should be scaled down accordingly. For example, the source region 105 and the drain region 106 should be ultra-shallow.

In further embodiments, the semiconductor substrate 101 is silicon or silicon-on-insulator, and the metal-semiconductor-compound nanowire is a metal silicide nanowire.

In some embodiments, the semiconductor substrate 101 is germanium or germanium-on-insulator, and the metal-semiconductor-compound nanowire is a metal germanide nanowire.

In one embodiment of the present invention, the semiconductor substrate 101 can be silicon or silicon-on-insulator, or germanium or germanium-on-insulator. It should be noted that the present invention is not thus limited—the semiconductor substrate 101 can be a semiconductor substrate of another type, such as gallium arsenide or any other III-V semiconductor substrate.

As discussed above, the present invention provides a method of making a nano-MOS device, which has a metal gate, thereby avoiding the poly depletion effect, and enhancing the MOS device's performance. The method forms metal gates by depositing a metal film over sidewall surfaces on two sides of a polysilicon layer. The metal in the metal film diffuses toward the sidewall surfaces of the polysilicon layer and forms, after annealing, metal-semiconductor compound nanowires (i.e., metal gates) on the sidewall surfaces of the polycrystalline semiconductor layer. Thus, high-resolution lithography is not required to form metal compound semiconductor nanowires, resulting in significant cost saving. At the same time, a nano-MOS device is also disclosed, which includes a metal gate, thereby avoiding the poly depletion effect, and resulting in enhanced MOS device performance.

Obviously, without departing from the spirit and scope of the present invention, those skilled in the art can make various improvements and modification. Thus, if such improvements and modifications fall into the scope of protection of the claims and their equivalents, the present invention intends to include such improvements and modifications.

1-19. (canceled)

20. A method of making a nano-MOS device, the method comprising:
providing a semiconductor substrate;
forming a gate oxide layer on the semiconductor substrate;
forming a patterned semiconductor layer on the gate oxide layer;
forming metal-semiconductor compound nanowires on sidewalls of the patterned semiconductor layer;
removing the patterned semiconductor layer; and
forming source/drain regions for the nano-MOS device whereby one or more of the metal-semiconductor-compound nanowires constitute a gate for the nano-MOS device.

21. The method of making the nano-MOS device according to claim 20, wherein the patterned semiconductor layer includes polysilicon, wherein the semiconductor substrate is silicon or silicon-on-insulator, and the metal-semiconductor-compound nanowires are metal silicide nanowires.

22. The method of making the nano-MOS device according to claim 20, wherein the patterned semiconductor layer includes polycrystalline germanium, wherein the semiconductor substrate is germanium or germanium-on-insulator, and the metal-semiconductor-compound nanowires are metal germanide nanowires.

23. The method of making the nano-MOS device according to claim 21, wherein the patterned semiconductor layer includes polycrystalline semiconductor, and wherein forming the metal-semiconductor compound nanowires further comprises:
depositing a metal film on the sidewalls to allow metal in the metal film to diffuse to the polycrystalline semiconductor;
removing part of the metal film remaining on the sidewalls; and
annealing the patterned semiconductor layer to form the metal/semiconductor compound nanowires on the sidewalls.

24. The method of making the nano-MOS device according to claim 23, wherein the metal-semiconductor-compound nanowires are formed from chemical reaction between the metal and the polycrystalline semiconductor layer, wherein, the metal is selected from the group consisting of nickel, cobalt, titanium, ytterbium, and any of nickel, cobalt, titanium, and ytterbium incorporated with platinum.

25. The method of making the nano-MOS device according to claim 24, wherein the metal is incorporated any of with tungsten and molybdenum.

26. The method of making the nano-MOS device according to claim 23, wherein the annealing is performed at a temperature of about 200˜900° C.

27. The method of making the nano-MOS device according to claim 23, wherein the metal film is deposited onto the sidewalls using a PVD process, wherein, during the deposition of the metal film, a target material is partially ionized into an ionic state so as to produce metal ions, wherein a first bias voltage is applied to the patterned semiconductor layer, and wherein the target material is partially ionized into the ionic state by applying a second bias voltage on the target material.

28. The method of making the nano-MOS device according to claim 27, wherein the first bias voltage is any of a direct current bias voltage, an alternating current bias voltage or a pulsed biase voltage, and wherein the second bias voltage is any of a direct current bias voltage, an alternating current bias voltage or a pulsed biase voltage.

29. The method of making the nano-MOS device according to claim 27, wherein the substrate is at a temperature of 0˜300° C. during the deposition of the metal film.

30. The method of making the nano-MOS device according to claim 20, further comprising
etching the gate oxide layer using the metal/semiconductor compound nanowires as mask; and
forming sidewalls on two sides of respective metal/semiconductor compound nanowires.

31. The method of making the nano-MOS device according to claim 20, wherein forming the patterned semiconductor layer further comprises:
forming consecutively a polycrystalline semiconductor layer and an insulating layer on the gate oxide layer; and
etching consecutively the insulating layer and the polycrystalline semiconductor layer to form the sidewalls.

32. The method of making the nano-MOS device according to claim 20, wherein the gate is about 2˜11 nm long.

33. The method of making the nano-MOS device according to claim 20, wherein the gate oxide layer is a high-K dielectric layer.

34. A nano-MOS device, comprising:
a semiconductor substrate;
a gate oxide layer formed over the semiconductor substrate;
a gate formed over the gate oxide layer, the gate including one or more metal-semiconductor-compound nanowires; and
source/drain regions formed in the semiconductor substrate on two sides of each of the one or more metal-semiconductor-compound nanowires; and
wherein the one or more metal-semiconductor-compound nanowires are formed by forming a patterned semiconductor layer on the gate oxide layer, forming the one or more metal-semiconductor-compound nanowires on one or more sidewalls of the patterned semiconductor layer, and removing the patterned semiconductor layer.

35. The nano-MOS device according to claim 34, wherein the gate is about 2˜11 nm long.

36. The nano-MOS device according to claim 34, wherein the gate oxide layer is a high-K dielectric layer.

37. The nano-MOS device according to claim 34, wherein the patterned semiconductor layer includes polysilicon, wherein the semiconductor substrate is silicon or silicon-on-insulator, and the metal-semiconductor-compound nanowires are metal silicide nanowires.

38. The nano-MOS device according to claim 34, wherein the patterned semiconductor layer includes polycrystalline germanium, wherein the semiconductor substrate is germanium or germanium-on-insulator, and the metal-semiconductor-compound nanowires are metal germanide nanowires.

39. The nano-MOS device according to claim 34, wherein the one or more metal-semiconductor-compound nanowires are formed from chemical reaction between metal and semiconductor, and wherein the metal is selected from the group consisting of nickel, cobalt, titanium, ytterbium, and any of nickel, cobalt, titanium, and ytterbium incorporated with one or more of platinum tungsten and molybdenum.
